(19) United States
(12) Patent Application Publication
(10) Pub. No.: US 2013/0328055 A1
(43) Pub. Date: Dec. 12, 2013

(54) SEMICONDUCTOR LIGHT EMITTING DEVICE

(71) Applicants: Jumpei TAJIMA, Tokyo (JP); Kotaro Zaima, Tokyo (JP); Shigeya Kimura, Kanagawa-ken (JP); Hiroshi Ono, Tokyo (JP); Shinji Yamada, Kanagawa-ken (JP); Satoshi Mitsugi, Kanagawa-ken (JP); Naoharu Sugiyama, Kanagawa-ken (JP); Shinya Nunoue, Chiba-ken (JP)

(72) Inventors: Jumpei TAJIMA, Tokyo (JP); Kotaro Zaima, Tokyo (JP); Shigeya Kimura, Kanagawa-ken (JP); Hiroshi Ono, Tokyo (JP); Shinji Yamada, Kanagawa-ken (JP); Satoshi Mitsugi, Kanagawa-ken (JP); Naoharu Sugiyama, Kanagawa-ken (JP); Shinya Nunoue, Chiba-ken (JP)

(21) Appl. No.: 13/724,007

(22) Filed: Dec. 21, 2012

(30) Foreign Application Priority Data
Jun. 11, 2012 (JP) 2012-132222

(51) Int. Cl. H01L 33/40

(52) U.S. Cl. CPC H01L 33/40
USPC 257/76

(57) ABSTRACT

According to one embodiment, a semiconductor light emitting device includes first and second electrodes, first, second and third semiconductor layers, and a light emitting layer. The first semiconductor layer of a first conductivity type is provided on the first electrode. The light emitting layer is provided on the first semiconductor layer. The second semiconductor layer of a second conductivity type is provided on the light emitting layer. The third semiconductor layer with low impurity concentration is provided on a part of the second semiconductor layer. The second electrode includes a pad section and a narrow wire section. The pad section is provided on the third semiconductor layer. The narrow wire section extends out from the pad section and includes an extending portion extending along a plane perpendicular to a stacking direction. The narrow wire section is in contact with the second semiconductor layer.

### CROSS-REFERENCE TO RELATED APPLICATIONS

This application is based upon and claims the benefit of priority from the prior Japanese Patent Application No. 2012-132222, filed on Jun. 11, 2012; the entire contents of which are incorporated herein by reference.

### FIELD

Embodiments described herein relate generally to a semiconductor light emitting device.

### BACKGROUND

Semiconductor light emitting devices such as light emitting diodes (LED) have been developed. Semiconductor light emitting devices are required to improve the efficiency. For instance, in order to suppress light emission at a position overlapping a pad having light blocking property, there is a configuration including an insulating layer for controlling the current path.

### BRIEF DESCRIPTION OF THE DRAWINGS

FIG. 1 is a schematic perspective view showing a semiconductor light emitting device according to a first embodiment;

FIG. 2 is a schematic sectional view showing the semiconductor light emitting device according to the first embodiment;

FIG. 3 is a schematic sectional view showing the semiconductor light emitting device according to the first embodiment;

FIG. 4A and FIG. 4B are schematic plan views showing the semiconductor light emitting device according to the first embodiment;

FIG. 5 is a schematic sectional view showing the semiconductor light emitting device according to the first embodiment;

FIG. 6 is a schematic sectional view showing the semiconductor light emitting device according to the first embodiment;

FIG. 7 is a flow chart showing a method for manufacturing a semiconductor light emitting device according to the first embodiment;

FIG. 8A to FIG. 8C are schematic views showing the semiconductor light emitting device according to the first embodiment;

FIG. 9 is a schematic sectional view showing a semiconductor light emitting device according to a second embodiment;

FIG. 10 is a schematic sectional view showing a semiconductor light emitting device according to a second embodiment;

FIG. 11 is a schematic plan view showing the semiconductor light emitting device according to the second embodiment;

FIG. 12 is a schematic sectional view showing another semiconductor light emitting device according to the second embodiment;

FIG. 13A to FIG. 13C are schematic plan views showing the another semiconductor light emitting device according to the second embodiment;

FIG. 14A and FIG. 14B are schematic plan views showing the characteristics of semiconductor light emitting devices;

FIG. 15 is a graph showing the characteristics of the semiconductor light emitting device;

FIG. 16A to FIG. 16C are schematic plan views showing another semiconductor light emitting device according to the second embodiment;

FIG. 17 to FIG. 19 are schematic sectional views showing other semiconductor light emitting devices according to the second embodiment;

FIG. 20A to FIG. 20H are schematic plan views showing the configuration and characteristics of semiconductor light emitting devices according to the second embodiment;

FIG. 21A to FIG. 21G are schematic sectional views showing semiconductor light emitting devices according to the embodiments.

### DETAILED DESCRIPTION

According to one embodiment, a semiconductor light emitting device includes a first electrode, a first semiconductor layer, a light emitting layer, a second semiconductor layer, a third semiconductor layer, and a second electrode. The first semiconductor layer of a first conductivity type is provided on the first electrode and includes a nitride semiconductor. The light emitting layer is provided on the first semiconductor layer and includes a nitride semiconductor. The second semiconductor layer of a second conductivity type is provided on the light emitting layer and includes a nitride semiconductor. The third semiconductor layer is provided on a part of the second semiconductor layer. The third semiconductor layer includes a nitride semiconductor. The third semiconductor layer has a concentration of impurity of the second conductivity type lower than a concentration of impurity of the second conductivity type in the second semiconductor layer. The second electrode includes a pad section and a narrow wire section. The pad section is provided on the third semiconductor layer. The narrow wire section extends out from the pad section. The narrow wire section includes an extending portion extending along a plane perpendicular to a stacking direction from the first semiconductor layer toward the second semiconductor layer. The narrow wire section is in contact with the second semiconductor layer.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present specification and the drawings, components similar to those described previously with reference to earlier figures are labeled with like reference numerals, and the detailed description thereof is omitted appropriately.

### First Embodiment

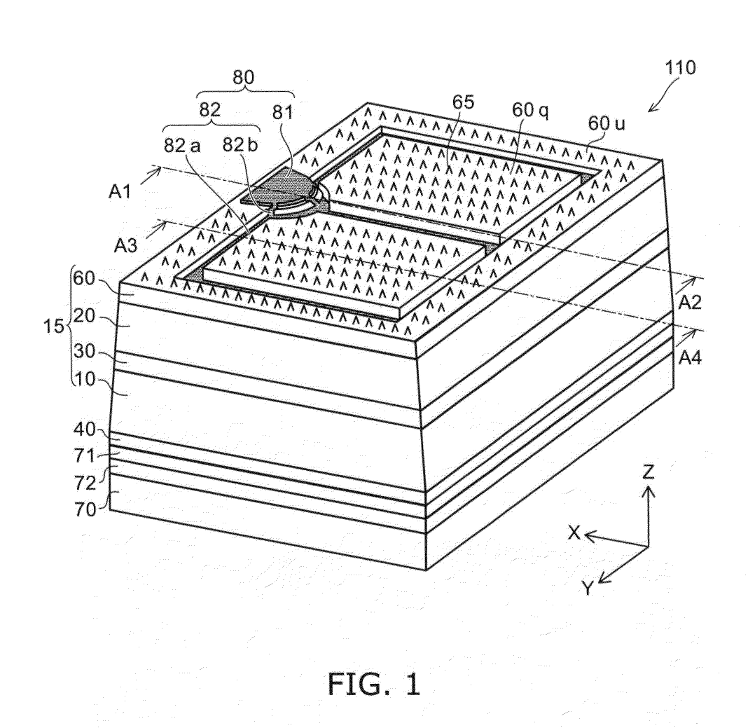

FIG. 1 is a schematic perspective view illustrating a semiconductor light emitting device according to a first embodiment.

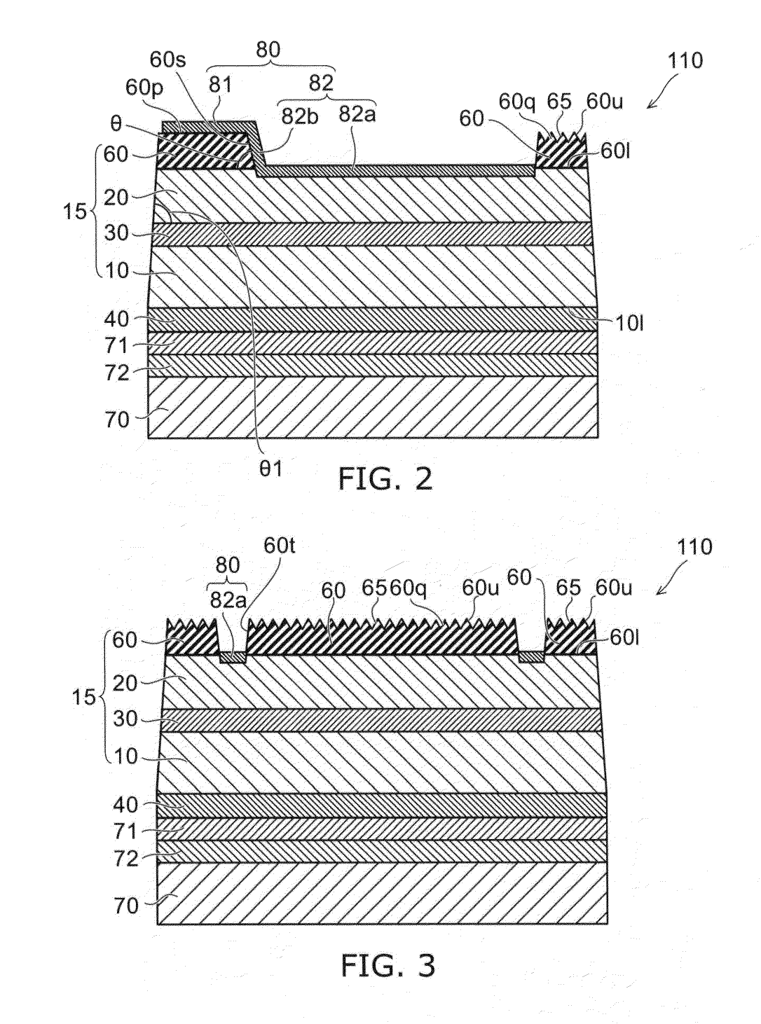

FIG. 2 and FIG. 3 are schematic sectional views illustrating the semiconductor light emitting device according to the first embodiment. FIG. 2 is a sectional view taken along line A1-A2 of FIG. 1. FIG. 3 is a sectional view taken along line A3-A4 of FIG. 1.

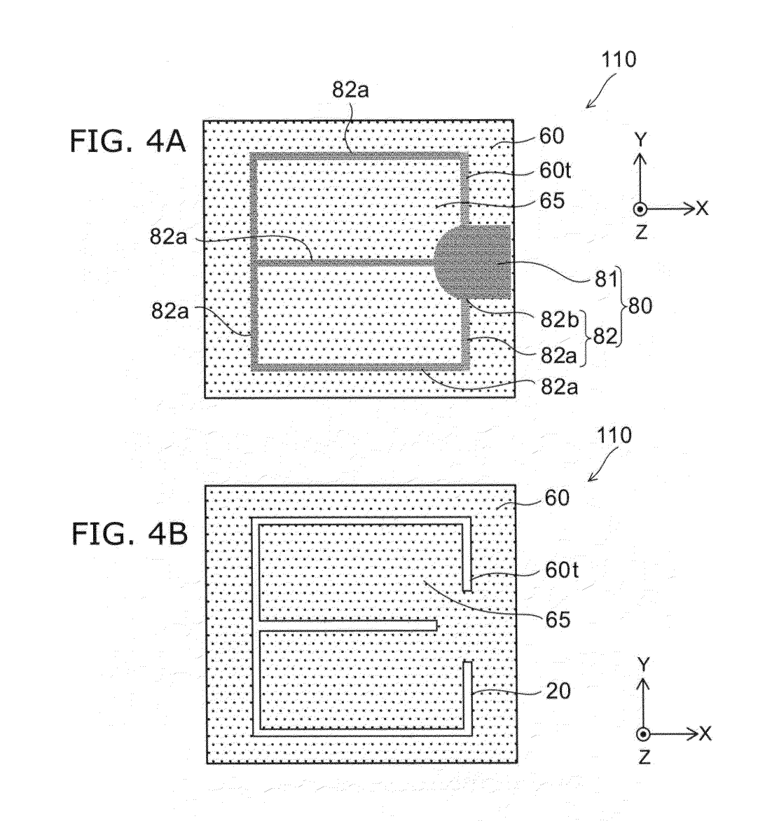

FIG. 4A and FIG. 4B are schematic plan views illustrating the semiconductor light emitting device according to the first embodiment. FIG. 4A illustrates the planar pattern of the second electrode 80 described later. FIG. 4B illustrates the planar pattern of the third semiconductor layer 60 described later.

As shown in FIG. 1, FIG. 2, FIG. 3, FIG. 4A, and FIG. 4B, the semiconductor light emitting device 110 according to the embodiment includes a first electrode 40, a first semiconductor layer 10, a light emitting layer 30, a second semiconductor layer 20, a third semiconductor layer 60, and a second electrode 80.

The first semiconductor layer 10 is provided on the first electrode 40. The first semiconductor layer 10 includes a nitride semiconductor and is of a first conductivity type. The light emitting layer 30 is provided on the first semiconductor layer 10 and includes a nitride semiconductor. The second semiconductor layer 20 is provided on the light emitting layer 30, includes a nitride semiconductor, and is of a second conductivity type.

For instance, the first conductivity type is p-type, and the second conductivity type is n-type. In the embodiment, the first conductivity type may be n-type, and the second conductivity type may be p-type. In the following description, it is assumed that the first conductivity type is p-type, and the second conductivity type is n-type.

The third semiconductor layer 60 is provided on part of the second semiconductor layer 20. The concentration of impurity of the second conductivity type in the third semiconductor layer 60 is lower than the concentration of impurity of the second conductivity type in the second semiconductor layer 20. The third semiconductor layer 60 includes a nitride semiconductor.

Thus, the semiconductor light emitting device 110 includes a stacked semiconductor layer 15 including the first semiconductor layer 10, the light emitting layer 30, the second semiconductor layer 20, and the third semiconductor layer 60.

The impurity of the first conductivity type (p-type) is at least one of e.g. Mg, Zn, and C. The impurity of the second conductivity type (n-type) is at least one of e.g. Si, Ge, Te, and Sn.

The second semiconductor layer 20 contains e.g. Si as the impurity of the second conductivity type. The concentration of Si in the third semiconductor layer 60 is lower than the concentration of Si in the second semiconductor layer 20.

The first semiconductor layer 10 includes e.g. a GaN layer containing p-type impurity (at least one of Mg, Zn, and C). The concentration of p-type impurity in the first semiconductor layer 10 is e.g. 1×10¹⁸ cm⁻³ or more and 5×10²¹ cm⁻³ or less. The first semiconductor layer 10 includes e.g. a p-side contact layer.

The second semiconductor layer 20 includes e.g. a GaN layer containing n-type impurity (at least one of Si, Ge, Te, and Sn). The concentration of n-type impurity in the second semiconductor layer 20 is e.g. 1×10¹⁷ cm⁻³ or more and 2×10¹⁹ cm⁻³ or less. The second semiconductor layer 20 includes e.g. an n-side contact layer.

The third semiconductor layer 60 includes e.g. a nitride semiconductor layer (at least one of e.g. a GaN layer, AlN layer, and AlGaN layer) not doped with n-type impurity (at least one of Si, Ge, Te, and Sn). The concentration of p-type or n-type impurity in the third semiconductor layer 60 is e.g. 1×10¹⁷ cm⁻³ or less. More preferably, the concentration of p-type or n-type impurity in the third semiconductor layer 60 is 1×10¹⁶ cm⁻³ or less (e.g., non-doped).

The concentration of impurity of the second conductivity type in the third semiconductor layer 60 is 0.5 times or less the concentration of impurity of the second conductivity type in the second semiconductor layer 20.

Examples of the stacked semiconductor layer 15 and the light emitting layer 30 are described later.

The stacking direction from the first semiconductor layer 10 toward the second semiconductor layer 20 is defined as Z-axis direction. One direction perpendicular to the Z-axis direction is defined as X-axis direction. The direction perpendicular to the Z-axis direction and the X-axis direction is defined as Y-axis direction.

For instance, the shape of the semiconductor light emitting device 110 as viewed along the Z-axis direction (planar shape) is a rectangle. One side of the planar shape of the semiconductor light emitting device 110 is directed along e.g. the X-axis direction. Another side of the planar shape of the semiconductor light emitting device 110 is directed along e.g. the Y-axis direction. However, in the embodiment, the relationship between the X-axis direction and the direction of the side of the semiconductor light emitting device 110 is arbitrary.

The second electrode 80 includes a pad section 81 and a narrow wire section 82. The pad section 81 is provided on the third semiconductor layer 60. The narrow wire section 82 extends out from the pad section 81 and is in contact with the second semiconductor layer 20. The narrow wire section 82 includes a narrow wire 82a and a connecting section 82b. The narrow wire 82a extends along the X-Y plane. The narrow wire 82a is in contact with the second semiconductor layer 20. The connecting section 82b is provided between the narrow wire 82a and the pad section 81. The connecting section 82b connects the narrow wire 82a and the pad section 81 to each other. The connecting section 82b extends along at least the side surface of the third semiconductor layer 60. Thus, the narrow wire section 82 includes a portion (narrow wire 82a) extending along the plane (X-Y plane) perpendicular to the stacking direction (Z-axis direction) from the first semiconductor layer 10 toward the second semiconductor layer 20.

The third semiconductor layer 60 has an upper surface 60u and a lower surface 601. The lower surface 601 of the third semiconductor layer 60 is opposed to the second semiconductor layer 20. The upper surface 60u is a surface on the opposite side from the lower surface 601. The upper surface 60u of the third semiconductor layer 60 includes a portion 60p covered with the second electrode 80 and a portion 60q not covered with the second electrode 80. In this example, the third semiconductor layer 60 has an unevenness 65. In the upper surface 60u of the third semiconductor layer 60, the unevenness 65 is provided on at least the portion 60q not covered with the second electrode 80.

The first electrode 40 is provided on the lower surface 101 of the first semiconductor layer 10. In this example, the semiconductor light emitting device 110 further includes a support substrate 70, a first intermediate conductive layer 71, and a second intermediate conductive layer 72. The support substrate 70 is conductive. The support substrate 70 is e.g. a conductive silicon substrate. On the support substrate 70, the first electrode 40 is provided. That is, the first electrode 40 is placed between the support substrate 70 and the first semiconductor layer 10. The first intermediate conductive layer 71 is provided between the support substrate 70 and the first electrode 40. The second intermediate conductive layer 72 is provided between the support substrate 70 and the first intermediate conductive layer 71.

For instance, the first intermediate conductive layer 71 is formed on the surface (lower surface 101) of the first electrode 40. The second intermediate conductive layer 72 is formed on the surface of the support substrate 70. The first intermediate conductive layer 71 and the second intermediate conductive layer 72 are opposed and bonded to each other. Thus, the support substrate 70 is bonded to the first electrode 40.

The first intermediate conductive layer 71 is e.g. an adhesive metal layer. The first intermediate conductive layer 71 is made of e.g. Ti or Ti alloy. The second intermediate conductive layer 72 is e.g. a bonding metal layer. The second intermediate conductive layer 72 is made of e.g. AuSn alloy.

The second electrode 80 and the first electrode 40 are made of metal (including alloy). The narrow wire section 82 of the second electrode 80 is made of the same material as at least part of the pad section 81. This provides good electrical characteristics and also simplifies manufacturing.

The semiconductor light emitting device 110 is e.g. a semiconductor light emitting device of the thin film type. As described later, in the semiconductor light emitting device 110, on a growth substrate, the third semiconductor layer 60, the second semiconductor layer 20, the light emitting layer 30, and the first semiconductor layer 10 are sequentially crystal grown. Then, a support substrate is bonded to the stacked semiconductor layer 15. Subsequently, the growth substrate is removed. Bonding of the support substrate to the stacked semiconductor layer 15 is performed e.g. via a bonding metal layer, or directly.

In the specification, the term “bonded” includes not only the state of being directly fixed, but also the state of being fixed with another element interposed in between. The term “provided on” includes not only the state of being placed in direct contact, but also the state of being placed with another element interposed in between. The term “opposed” includes not only the state of facing directly, but also facing indirectly with another element interposed in between. The term “stacked” includes not only the state of being stacked in contact with each other, but also the state of being stacked with another layer interposed in between.

In the semiconductor light emitting device 110, a voltage is applied between the second electrode 80 and the first electrode 40. Through the first semiconductor layer 10 and the second semiconductor layer 20, a current is supplied to the light emitting layer 30. Thus, light is emitted from the light emitting layer 30. The peak wavelength of the light emission is e.g. 370 nanometers (nm) or more and 700 nm or less. The light is emitted outside primarily from the upper surface of the semiconductor light emitting device 110.

In an upper portion of the second semiconductor layer 20, for instance, an n-side contact layer is provided. This n-side contact layer is in contact with the narrow wire 82a. The narrow wire 82a is in ohmic contact with the second semiconductor layer 20 (specifically, the n-side contact layer).

On the other hand, the impurity concentration in the third semiconductor layer 60 is low. The electrical resistance of the third semiconductor layer 60 is twice or more the electrical resistance of the second semiconductor layer 20. Thus, the electrical resistance between the pad section 81 provided on the upper surface 60u of the third semiconductor layer 60 and the third semiconductor layer 60 is higher than the electrical resistance between the narrow wire 82a and the second semiconductor layer 20.

Thus, when a voltage is applied between the second electrode 80 and the first electrode 40, a current flows between the narrow wire section 82 (narrow wire 82a) of the second electrode 80 and the second semiconductor layer 20. However, no substantial current flows between the pad section 81 of the second electrode 80 and the third semiconductor layer 60. This suppresses light emission immediately below the pad section 81 and therearound. Light emission occurs below the narrow wire section 82 (narrow wire 82a) and therearound.

From the viewpoint of electrical connectivity, the pad section 81 is made of metal (including alloy). If light emission occurs immediately below the pad section 81 and therearound, the light is blocked by the pad section 81. The light is not directly emitted to the outside of the device and causes loss.

In contrast, in the embodiment, the pad section 81 is provided on the third semiconductor layer 60 having low impurity concentration. This suppresses light emission immediately below the pad section 81 and therearound. Thus, a current is injected from the narrow wire section 82 (narrow wire 82a) to the second semiconductor layer 20. This promotes light emission in the portion other than the pad section 81.

The narrow wire section 82 extends in the X-Y plane and has the function of spreading the current in the X-Y plane. The current flowing in the semiconductor layer spreads to some extent. Thus, the current injected from the narrow wire section 82 flows not only in the semiconductor layer immediately below the narrow wire section 82, but also in the portion other than immediately below the narrow wire section 82. Accordingly, a relatively uniform current flows in the light emitting layer 30. Thus, the current flowing in the semiconductor layer spreads. Hence, the width of the narrow wire section 82 (the length in the direction perpendicular to the extending direction of the narrow wire section 82) can be set relatively narrow. The light emitted immediately below the narrow wire section 82 is reflected by e.g. the interface of the layers or the first electrode 40 and changes its direction. With a relatively small number of times of reflections, the light can be emitted out from the upper surface of the device. Thus, the loss due to absorption occurring before light extraction is low.

On the other hand, from the viewpoint of electrical connectivity of bonding and the like, the size (width) of the pad section 81 is set relatively large. Thus, if light emission occurs immediately below the pad section 81, then in order for the light to be emitted out from the upper surface of the device, the light is reflected by e.g. the interface of the layers or the first electrode 40 and changes its direction with a large number of times of reflections. This causes high loss. Thus, it is desired to suppress light emission immediately below the pad section 81 as much as possible.

In the embodiment, the pad section 81 is provided on the third semiconductor layer 60 having low impurity concentration. This suppresses light emission immediately below the pad section 81 and therearound. Thus, the loss can be suppressed. Accordingly, high efficiency is achieved.

In the embodiment, the area of the third semiconductor layer 60 in the X-Y plane is preferably 2% or more and 10% or less of the area of the second semiconductor layer 20 in the X-Y plane. If the area of the third semiconductor layer 60 in the X-Y plane is in this range, the area of the narrow wire section 82 of the second electrode 80 is ensured. This promotes light emission. If the area of the third semiconductor layer 60 in the X-Y plane is too large, light extraction is hampered. If the area is too small, the current injection may become insufficient.

In the embodiment, the ratio (S2/S1) of the area S2 of the pad section 81 in the X-Y plane to the area S1 of the second electrode 80 in the X-Y plane is 20% or more and 65% or less. When the pad section 81 has such a large area, the effect of efficiency improvement by the embodiment is easily achieved.

The width of the narrow wire section 82a along the direction (e.g., Y-axis direction) orthogonal to the extending direction of the narrow wire section 82 is preferably 6% or more and 15% or less of the width of the pad section 81 in that direction (the width along the Y-axis direction). In this range, the light extraction efficiency can be increased while sufficiently injecting the current from the narrow wire section 82 of the second electrode 80.

Here, in order to suppress current injection from the pad section 81, it is possible to consider a configuration in which an insulating layer made of e.g. SiO₂ is provided on part of the second semiconductor layer 20 without providing the third semiconductor layer 60. However, such an insulating layer has lower thermal conductivity than nitride semiconductor. Thus, heat is easily accumulated in the insulating layer. Furthermore, the insulating layer made of a material different from nitride semiconductor has low adhesiveness to the nitride semiconductor. This may decrease the reliability. Furthermore, the difference in thermal expansion coefficient therebetween causes defects such as cracks, and is likely to decrease the reliability. Moreover, the adhesiveness between the insulating layer made of e.g. SiO₂ and the metal (e.g., Al) used for the second electrode 80 is low. The number of process steps is also increased.

In contrast, in the embodiment, the third semiconductor layer 60 made of a nitride semiconductor having good thermal conductivity is used to suppress current injection from the pad section 81. Thus, heat is not easily accumulated. Furthermore, the third semiconductor layer 60 is made of a material similar to those of the other semiconductor layers. This provides high adhesiveness. Furthermore, there occurs no difference in thermal expansion coefficient. This suppresses defects such as cracks and provides high reliability. The adhesiveness between the third semiconductor layer 60 made of nitride semiconductor and the metal (e.g., Al) used for the second electrode 80 is high. The third semiconductor layer 60 is grown before growth of the second semiconductor layer 20. Thus, there is no increase in the number of process steps.

By controlling the conductivity of the third semiconductor layer 60, the ratio between the current injected from the pad section 81 into the semiconductor layer and the current injected from the narrow wire section 82 into the semiconductor layer can be set to an arbitrary ratio. Thus, below the pad section 81, by providing the third semiconductor layer 60 rather than an insulating layer, the current density around the pad section 81 can be adjusted to an appropriate state, and the light emission distribution can be made close to a more desirable state. This further increases the efficiency.

For instance, in the case where the third semiconductor layer 60 is not provided, the local light emission intensity around the pad section 81 is approximately 1.5 times that in the other portion. Then, the current can be made uniform by setting the current density in the third semiconductor layer 60 to approximately 1/1.5 of the current density in the second semiconductor layer 20. To this end, for instance, the resistance of the third semiconductor layer 60 is set to 1.5 times the resistance of the second semiconductor layer 20.

The resistance of the third semiconductor layer 60 is based on the thickness of the third semiconductor layer 60 and the conductivity of the third semiconductor layer 60 (based on e.g. impurity concentration). The resistance of the second semiconductor layer 20 is based on the thickness of the second semiconductor layer 20 and the conductivity of the second semiconductor layer 20 (based on e.g. impurity concentration). The conductivity of the third semiconductor layer 60 is determined in consideration of the thickness.

Furthermore, in the case where the second semiconductor layer 20 is of n-type, electrons are injected from the second electrode 80 into the second semiconductor layer. The electron injection efficiency is high. Thus, if the pad section 81 is also brought into contact with the second semiconductor layer 20 without providing the third semiconductor layer 60, electrons are injected from the pad section 81 and its neighborhood into the second semiconductor layer 20. This suppresses electron injection from the narrow wire section 82. That is, the current is locally injected only from the neighborhood of the pad section 81, and no current is injected from the narrow wire section 82. Thus, light emission occurs locally in the pad section 81 and its neighborhood where light is not easily extracted, and light emission in the other portion is decreased. That is, the in-plane light emission distribution is non-uniform, and the light extraction efficiency is decreased.

In contrast, in the embodiment, even in the case where the second semiconductor layer 20 is of n-type, the pad section 81 is provided on the third semiconductor layer 60 having high resistance. This suppresses injection from the pad section 81 and its neighborhood into the second semiconductor layer 20. Thus, the in-plane light emission distribution is made uniform, and high light extraction efficiency is achieved. As a result, the efficiency is high.

Thus, in the case where the first conductivity type is p-type and the second conductivity type is n-type, the improvement of high light extraction efficiency according to the embodiment is made more effective.

As shown in FIG. 4B, the third semiconductor layer 60 is provided on part of the second semiconductor layer 20. For instance, in the third semiconductor layer 60, a trench 60t penetrating through the third semiconductor layer 60 is provided. The trench 60t reaches the second semiconductor layer 20. In the trench 60t, the second semiconductor layer 20 is exposed.

As shown in FIG. 4A, the narrow wire 82a of the narrow wire section 82 of the second electrode 80 is provided so as to be embedded in the trench 60t.

In the embodiment, the narrow wire section 82 has the function of spreading the current in the X-Y plane. Thus, preferably, the narrow wire section 82 is provided in a plurality. The planar shape (the shape as projected on the X-Y plane) of the narrow wire section 82 may be either a closed shape or an open shape.

As illustrated in FIG. 2 and FIG. 3, in this example, the narrow wire 82a is embedded in the second semiconductor layer 20. Thus, at least part of the narrow wire section 82 may be embedded in the second semiconductor layer 20. If at least part of the narrow wire section 82 (narrow wire 82a) is embedded in the second semiconductor layer 20, the side surface of the narrow wire section 82 is brought into contact with the second semiconductor layer 20 in addition to the contact between the bottom surface of the narrow wire section 82 and the second semiconductor layer 20. This can further reduce the electrical resistance between the narrow wire section 82 and the second semiconductor layer 20.

The second electrode 80 and the first electrode 40 are preferably reflective to the light emitted from the light emitting layer 30. This can increase the light extraction efficiency.

For instance, the second electrode 80 preferably contains Al. Al has good ohmic contact with n-type nitride semiconductor. The second electrode 80 containing Al or Al-containing alloy provides high reflectivity and high electrical characteristics.

The first electrode 40 preferably contains Ag. Ag has good ohmic contact with p-type nitride semiconductor. The first electrode 40 containing Ag or Ag-containing alloy provides high reflectivity and high electrical characteristics.

For instance, the depth of the unevenness 65 is 0.8 times or more the peak wavelength of the light emitted from the light emitting layer 30. For instance, the depth of the unevenness 65 is 5 times or less the peak wavelength of the light. By the unevenness 65, the light emitted from the light emitting layer 30 can be efficiently extracted to the outside of the device.

As illustrated in FIG. 2, the narrow wire section 82 extends out from the pad section 81 along the side surface 60s of the third semiconductor layer 60, and extends on the second semiconductor layer 20. That is, the pad section 81 provided on the third semiconductor layer 60 and the narrow wire 82a in contact with the second semiconductor layer 20 are connected by the connecting section 82b located therebetween. Here, to avoid breaking in the connecting section 82b, the side surface 60s of the third semiconductor layer 60 is preferably forward tapered.

For instance, the angle θ between the X-Y plane and the portion of the side surface 60s of the third semiconductor layer 60 where the second electrode 80 is provided is preferably 20 degrees or more and 85 degrees or less.

The taper angle θ of the side surface 60s of the third semiconductor layer 60 is adjusted by e.g. the etching condition for processing the third semiconductor layer 60. The condition for processing the third semiconductor layer 60 can be made similar to the condition for processing the stacked semiconductor layer 15 for division into devices. This improves the processing stability. In this case, the taper angle θ of the side surface 60s of the third semiconductor layer 60 is substantially equal to the taper angle of the side surface of the stacked semiconductor layer 15. For instance, the angle θ between the X-Y plane and the portion of the side surface 60s of the third semiconductor layer 60 where the second electrode 80 is provided is preferably equal to the angle θ1 between the X-Y plane and the side surface of the second semiconductor layer 20.

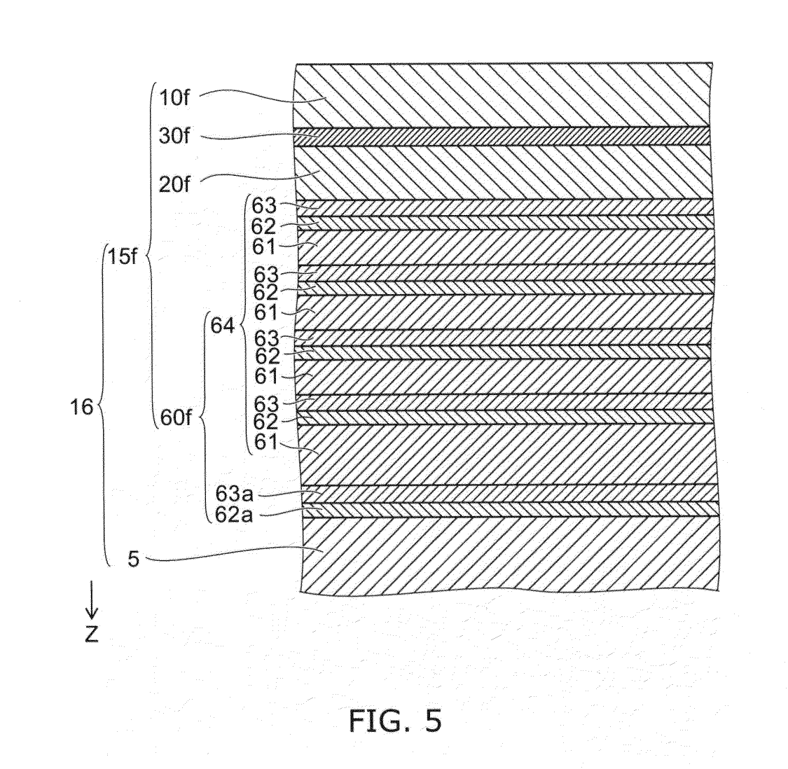

FIG. 5 is a schematic sectional view illustrating the semiconductor light emitting device according to the first embodiment. FIG. 5 illustrates the state of the stacked semiconductor layer 15 being crystal grown. That is, FIG. 5 illustrates the state of the semiconductor light emitting device 110 in one manufacturing step.

As shown in FIG. 5, on a growth substrate 5, a stacked semiconductor film 15f is epitaxially grown. The stacked semiconductor film 15f constitutes a stacked semiconductor layer 15. The method for growing the stacked semiconductor film 15f can be e.g. the metal-organic chemical vapor deposition (MOCVD) method or the metal-organic vapor phase epitaxy method. The growth substrate 5 and the stacked semiconductor film 15f are included in a stacked body 16.

The growth substrate 5 is made of e.g. silicon (Si). The embodiment is not limited thereto. For instance, the growth substrate 5 is made of one of Si, SiO₂, quartz, sapphire, GaN, SiC, and GaAs. Here, the surface orientation of the growth substrate 5 is arbitrary. In the following, an example of using a Si substrate as the growth substrate 5 is described.

On the growth substrate 5, a third semiconductor film 60f is formed. The third semiconductor film 60f constitutes at least part of a third semiconductor layer 60. On the third semiconductor film 60f, a second semiconductor film 20f is provided. The second semiconductor film 20f constitutes a second semiconductor layer 20. On the second semiconductor film 20f, a light emitting film 30f is provided. The light emitting film 30f constitutes a light emitting layer 30. On the light emitting film 30f, a first semiconductor film 10f is provided. The first semiconductor film 10f constitutes a first semiconductor layer 10.

In this example, as the third semiconductor film 60f, for instance, an AlN layer 62a, an AlGaN layer 63a, and a stacked intermediate layer 64 are provided. The AlN layer 62a is formed on the growth substrate 5.

The AlN layer 62a is formed by low temperature growth or high temperature growth.

In the case of low temperature growth, the formation temperature of the AlN layer 62a is e.g. 400° C. or more and 500° C. or less. In the case of low temperature growth, the thickness of the AlN layer 62a is e.g. 30 nm or more and 100 nm or less.

In the case of high temperature growth, the formation temperature of the AlN layer 62a is e.g. 700° C. or more and 1200° C. or less. In the case of high temperature growth, the thickness of the AlN layer 62a is e.g. 100 nm or more and 300 nm or less.

The AlN layer 62a may be a stacked film of a low temperature growth AlN layer and a high temperature growth AlN layer.

The AlGaN layer 63a is formed on the AlN layer 62a. The formation temperature of the AlGaN layer 63a is e.g. 800° C. or more and 1200° C. or less. The thickness of the AlGaN layer 63a is e.g. 300 nm or more and 2000 nm or less. The Al composition ratio in the AlGaN layer 63a is 0.15 or more and less than 1. The AlGaN layer 63a may include a stacked film of a plurality of layers different in Al composition ratio. The AlGaN layer 63a may have a continuous change of composition ratio.

The stacked intermediate layer 64 is formed on the AlGaN layer 63a. The stacked intermediate layer 64 includes a plurality of first layers 61 and a plurality of second layers 62. The plurality of first layers 61 and the plurality of second layers 62 are alternately stacked. In this example, a third layer 63 is provided between the first layer 61 and the second layer 62. The second layer 62 is provided on the first layer 61, and the third layer 63 is provided on the second layer 62. Another first layer 61 is provided on the third layer 63.

The Al composition ratio in the second layer 62 is higher than the Al composition ratio in the first layer 61. The first layer 61 is made of e.g. GaN. The second layer 62 is made of e.g. Alₓ₁Ga₁₋ₓN (0<x1≦1). The third layer 63 is made of Alₓ₂Ga₁₋ₓ₂N (0<x2<x1).

The thickness of the first layer 61 is e.g. 150 nm or more and 1000 nm or less. The thickness of the second layer 62 is e.g. 10 nm or more and 200 nm or less. The thickness of the third layer 63 is e.g. 20 nm or more and 300 nm or less. Here, the number of stacked layers (the number of first layers 61 or the number of second layers 62) is 1 or more and 5 or less.

The total thickness of the stacked intermediate layer 64 is e.g. 200 nm or more and 7500 nm or less. The formation temperature of the first layer 61 is e.g. 800° C. or more and 1100° C. or less. The formation temperature of the second layer 62 is e.g. 500° C. or more and 800° C. or less. The formation temperature of the third layer 63 is e.g. 700° C. or more and 1200° C. or less.

In this example, on the AlGaN layer 63a, the first layer 61 is provided. On the last third layer 63, the second semiconductor film 20f is provided.

The uppermost third layer 63 (AlGaN layer) is in contact with e.g. the second semiconductor film 20f (second semiconductor layer 20). However, in the embodiment, another layer may be provided between the uppermost third layer 63 and the second semiconductor film 20f (second semiconductor layer 20). For instance, the semiconductor light emitting device 110 may further include a stacked film provided between the uppermost third layer 63 and the second semiconductor film 20f (second semiconductor layer 20). This stacked film includes e.g. a plurality of high bandgap energy layers and a plurality of low bandgap energy layers stacked alternately. The high bandgap energy layer is e.g. a GaN layer. The low bandgap energy layer is e.g. an InGaN layer. This stacked film provides e.g. good crystallinity. This stacked film may be regarded as e.g. part of the third semiconductor film 60f (third semiconductor layer 60).

The uppermost layer in the stacked intermediate layer 64 may be a layer other than the third layer 63 (AlGaN layer). For instance, the first layer 61 (e.g., GaN layer) may be placed on top of the stacked intermediate layer 64. Alternatively, the second layer 62 (e.g., AlN layer) may be placed on top of the stacked intermediate layer 64.

In the semiconductor light emitting device 110, the third semiconductor layer 60 includes e.g. at least part of the stacked intermediate layer 64. The third semiconductor layer 60 includes the first layer 61. The third semiconductor layer 60 further includes e.g. the third layer 63. The third semiconductor layer 60 includes e.g. the second layer 62. The third semiconductor layer 60 may further include the AlN layer 62a and the AlGaN layer 63a.

Thus, the third semiconductor layer 60 can include a GaN layer (e.g., first layer 61). The concentration of impurity of the second conductivity type in this GaN layer is 1×10¹⁷/cm³ or less.

The third semiconductor layer 60 can include an Alₓ₁Ga₁₋ₓ₁N layer (0<x1≦1), i.e., at least one of the second layer 62 and the third layer 63.

That is, the third semiconductor layer 60 can include a nitride semiconductor stacked film. This nitride semiconductor stacked film can include an Al_{z1}Ga_{1-z1}N layer (0<z1<1), an Al_{z2}Ga_{1-z2}N layer (z1<z2≦1) provided on the Al_{z1}Ga_{1-z1}N layer, and an Al_{z3}Ga_{1-z3}N layer (0≦z3<x1) provided on the Al_{z2}Ga_{1-z2}N layer. The Al_{z1}Ga_{1-z1}N layer is e.g. the third layer 63. The Al_{z2}Ga_{1-z2}N layer is e.g. the second layer 62. The Al_{z3}Ga_{1-z3}N layer (0≦z3<x1) is e.g. the first layer 61.

This nitride semiconductor stacked film may be stacked in a plurality in the stacking direction (Z-axis direction).

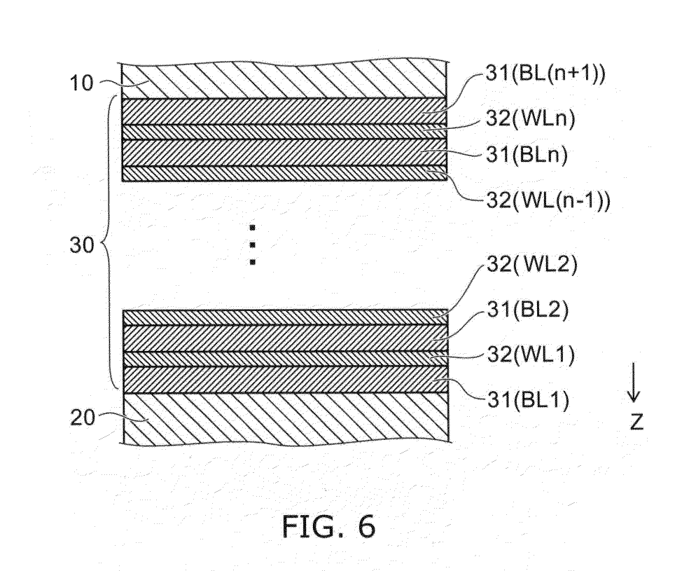

FIG. 6 is a schematic sectional view illustrating the semiconductor light emitting device according to the first embodiment. FIG. 6 shows an example configuration of the light emitting layer 30.

As shown in FIG. 6, the light emitting layer 30 includes a plurality of barrier layers 31 and a well layer 32 provided between the plurality of barrier layers 31. For instance, a plurality of barrier layers 31 and a plurality of well layers 32 are alternately stacked along the Z-axis direction.

The well layer 32 includes Inₓ₀Ga₁₋ₓ₀N (0<x0<1). The barrier layer 31 includes GaN. That is, the well layer 32 contains In, and the barrier layer 31 does not substantially contain In. The bandgap energy in the barrier layer 31 is larger than the bandgap energy in the well layer 32.

The light emitting layer 30 can have a single quantum well (SQW) configuration. In this case, the light emitting layer 30 includes two barrier layers 31 and a well layer 32 provided between the barrier layers 31. Alternatively, the light emitting layer 30 can have a multiple quantum well (MQW) configuration. In this case, the light emitting layer 30 includes three or more barrier layers 31 and well layers 32 each provided between a pair of barrier layers 31.

More specifically, the light emitting layer 30 includes e.g. n+1 barrier layers 31 and n well layers 32 (n is an integer of 2 or more). The (i+1)-th barrier layer BL(i+1) is placed between the i-th barrier layer BLi and the first semiconductor layer 10 (i is an integer of 1 or more and n−1 or less). The (i+1)-th well layer WL(i+1) is placed between the i-th well layer WLi and the first semiconductor layer 10. The first barrier layer BL1 is provided between the second semiconductor layer 20 and the first well layer WL1. The n-th well layer WLn is provided between the n-th barrier layer BLn and the (n+1)-th barrier layer BL(n+1). The (n+1)-th barrier layer BL(n+1) is provided between the n-th well layer WLn and the first semiconductor layer 10.

In the following, an example method for manufacturing the semiconductor light emitting device 110 is described.

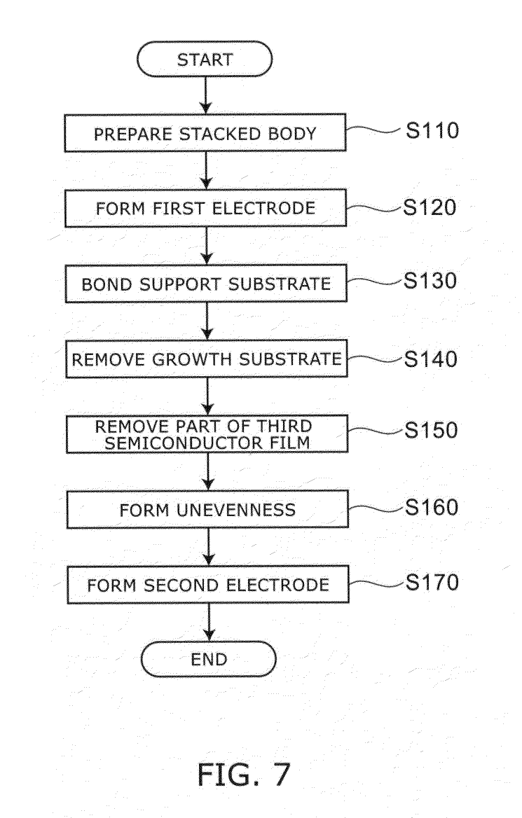

FIG. 7 is a flow chart illustrating a method for manufacturing a semiconductor light emitting device according to the first embodiment.

As shown in FIG. 7, a stacked body 16 is prepared (step S110). The stacked body 16 includes a growth substrate 5 and a stacked semiconductor film 15f. The stacked semiconductor film 15f includes a first semiconductor film 10f of the first conductivity type, a second semiconductor film 20f of the second conductivity type provided between the growth substrate 5 and the first semiconductor film 10f, a light emitting film 30f provided between the first semiconductor film 10f and the second semiconductor film 20f, and a third semiconductor film 60f provided between the growth substrate 5 and the second semiconductor film 20f and having a lower impurity concentration of the second conductivity type than the second semiconductor film 20f.

The manufacturing method may include the step of forming a stacked body 16 (i.e., the step of growing a stacked semiconductor film 15f on the growth substrate 5).

As shown in FIG. 7, a first electrode 40 is formed (step S120). For instance, an Ag film constituting the first electrode 40 is formed entirely on the upper surface of the workpiece. The thickness of the Ag film is e.g. 100 nm or more and 400 nm or less. Furthermore, on the Ag film, a Ti film constituting a first intermediate conductive layer 71 is formed. The thickness of this Ti film is e.g. 5 nm or more and 100 nm or less. The first intermediate conductive layer 71 functions as a barrier metal.

As shown in FIG. 7, a conductive support substrate 70 is bonded to the first electrode 40 (step S130). For instance, as the support substrate 70, a silicon substrate with a second intermediate conductive layer 72 (e.g., AuSn layer) provided on the major surface is prepared. The first electrode 40 and the support substrate 70 are placed so that the first intermediate conductive layer 71 and the second intermediate conductive layer 72 are opposed to each other. Then, the first intermediate conductive layer 71 and the second intermediate conductive layer 72 are brought into contact with each other and heated to bond the first electrode 40 and the support substrate 70.

As shown in FIG. 7, the growth substrate 5 is removed (step S140). This removal is performed by e.g. at least one processing of grinding and etching.

As shown in FIG. 7, part of the third semiconductor film 60f is removed (step S150). For instance, in the third semiconductor film 60f, a trench (trench 60t) penetrating through the third semiconductor film 60f is formed.

As shown in FIG. 7, an unevenness 65 is formed on the surface of the third semiconductor film 60f. Formation of this unevenness 65 can be based on e.g. wet processing with KOH and the like, or arbitrary dry etching processing and the like.

As shown in FIG. 7, a second electrode 80 is formed (step S170). For instance, after a resist having a prescribed shape is formed on the workpiece, a conductive film is formed, and then the resist is removed. Thus, a conductive film having a prescribed shape is formed. Part of this conductive film is in contact with the second semiconductor film 20f (second semiconductor layer 20) via the trench 60t. Thus, the narrow wire section 82 and the pad section 81 of the second electrode 80 are formed.

Thus, the semiconductor light emitting device 110 is obtained.

The order of the above steps S110-S170 can be interchanged as long as technically feasible. At least two of the steps S110-S170 may be simultaneously performed as long as technically feasible.

The method for manufacturing a semiconductor light emitting device according to the embodiment can provide a method for manufacturing a semiconductor light emitting device having high efficiency.

At the time of removing the growth substrate 5 described above (step S140), part of the third semiconductor film 60f formed on the growth substrate 5 is left, and another part is removed. For instance, in the third semiconductor film 60f, the AlN layer 62a and the AlGaN layer 63a are removed, and at least part of the stacked intermediate layer 64 remains. For instance, the remaining part of the stacked intermediate layer 64 constitutes a third semiconductor layer 60.

The unevenness 65 is formed on e.g. at least part of the remaining stacked intermediate layer 64. Part of the unevenness 65 may reach the second semiconductor layer 20.

FIG. 8A to FIG. 8C are schematic views illustrating the semiconductor light emitting device according to the first embodiment.

FIG. 8A and FIG. 8B show the result of SIMS (secondary ion mass spectrometry) analysis. In this analysis, a stacked semiconductor film 15f is formed on the growth substrate 5, and then the growth substrate 5 is removed. Then, elements contained in the semiconductor layers are analyzed from the surface of the first semiconductor layer 10. The horizontal axis in these figures represents position in the Z-axis direction (depth direction). The vertical axis of FIG. 8A represents the Al ion intensity (counts/sec), denoted as C(Al). The vertical axis of FIG. 8B represents the concentration of Si, denoted as C(Si). FIG. 8C schematically illustrates the semiconductor layers corresponding to the horizontal axis of FIGS. 8A and 8B.

As shown in FIG. 8A, in part of the first semiconductor layer 10, the concentration of Al is high. This portion of high Al concentration corresponds to the electron overflow suppressing layer. In the light emitting layer 30 and the second semiconductor layer 20, the Al concentration is low. In the third semiconductor layer 60, the Al concentration is high in the third layer 63 and the second layer 62. In the first layer 61, the Al concentration is low.

As illustrated in FIG. 8A, in the first layer 61, the second layer 62, and the third layer 63, the concentration of Al may change continuously. Alternatively, the concentration of Al may change discontinuously. In some cases, the boundary between the first layer 61, the second layer 62, and the third layer 63 is unclear. However, there are portions in which the Al concentration is high, low, and intermediate. Thus, the presence of the first layer 61, the second layer 62, and the third layer 63 can be identified.

As illustrated in FIG. 8B, in the first semiconductor layer 10, the concentration of Si is low. In the second semiconductor layer 20, the concentration of Si is high. In this example, in the light emitting layer 30, Si is observed. The concentration of Si in the light emitting layer 30 is lower than the concentration of Si in the second semiconductor layer 20.

In this example, in part of the third semiconductor layer 60 on the second semiconductor layer 20 side (third layer 63), a high concentration of Si is detected (portion PA of FIG. 8B). In this portion, fluctuation of Si concentration occurs. Except the portion PA, the concentration of Si in the third semiconductor layer 60 is lower than the concentration of Si in the second semiconductor layer 20. Thus, between the second semiconductor layer 20 and the portion of the third semiconductor layer 60 where the impurity concentration of the second conductivity type is lower than the impurity concentration of the second conductivity type in the second semiconductor layer 20, there may be a portion where the impurity concentration of the second conductivity type is locally higher than that in the second semiconductor layer 20 (the portion PA where the fluctuation of Si concentration occurs). In this case, the portion where the impurity concentration of the second conductivity type is lower than the impurity concentration of the second conductivity type in the second semiconductor layer 20 can be regarded as the third semiconductor layer 60.

The concentration of Si (impurity of the second conductivity type) in the first layer 61 (GaN layer) of the third semiconductor layer 60 is 1×10¹⁷/cm³ or less.

### Second Embodiment

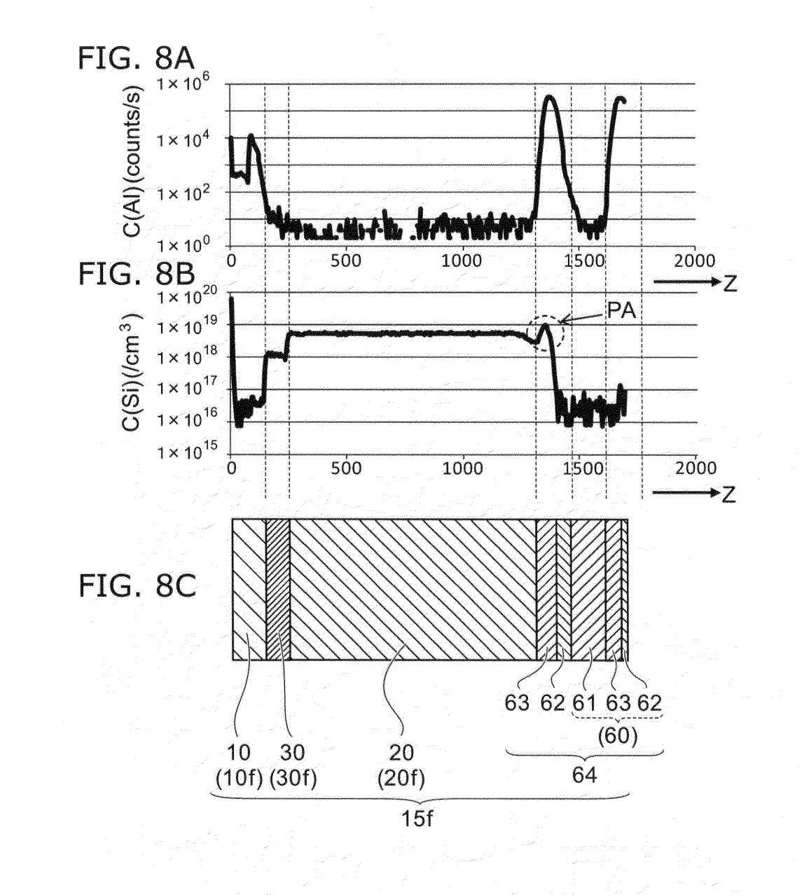

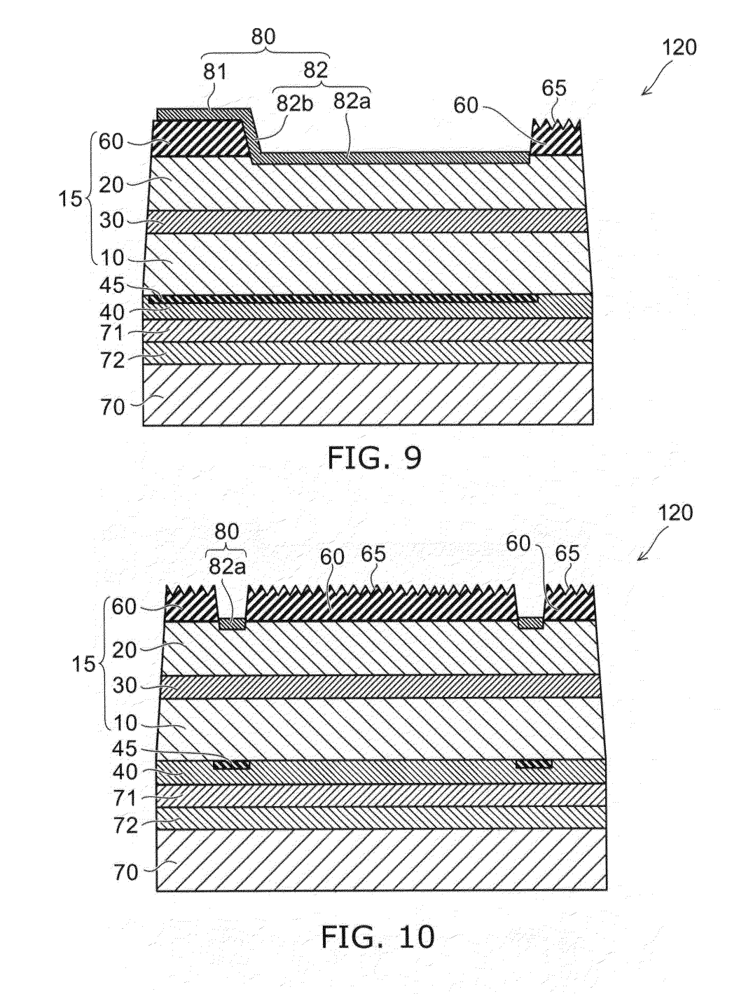

FIG. 9 and FIG. 10 are schematic sectional views illustrating a semiconductor light emitting device according to a second embodiment. FIG. 9 is a sectional view corresponding to the cross section taken along line A1-A2 of FIG. 1. FIG. 10 is a sectional view corresponding to the cross section taken along line A3-A4 of FIG. 1.

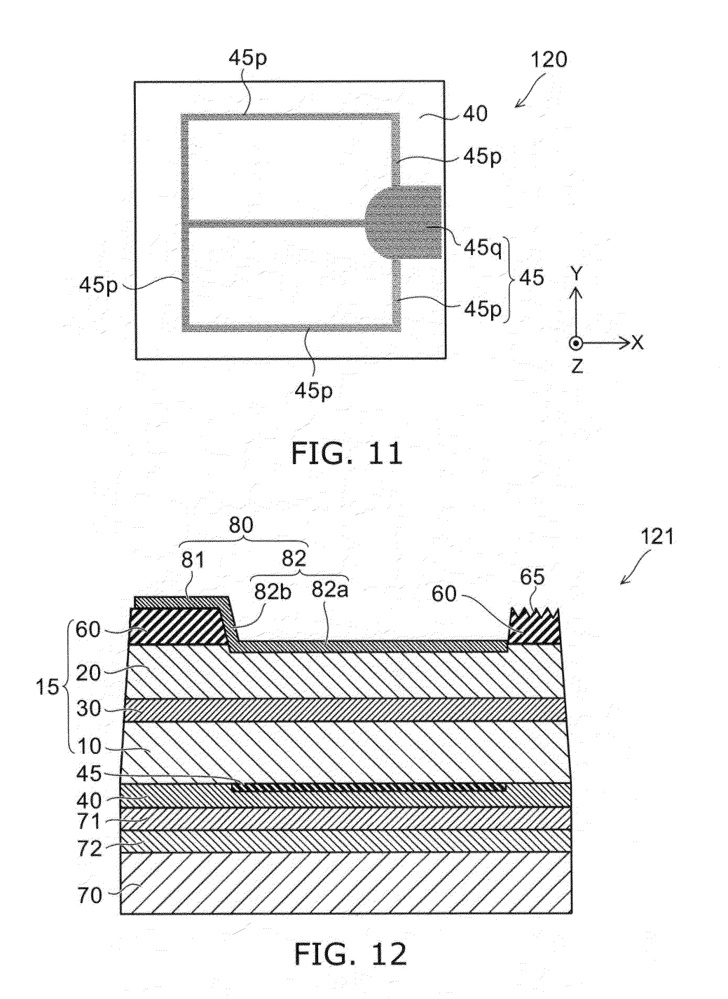

FIG. 11 is a schematic plan view illustrating the semiconductor light emitting device according to the second embodiment. FIG. 11 illustrates the planar pattern of the high resistance part 45 described later.

As shown in FIG. 9 to FIG. 11, the semiconductor light emitting device 120 according to the embodiment includes a first semiconductor layer 10, a light emitting layer 30, a second semiconductor layer 20, a third semiconductor layer 60, a second electrode 80, and a first electrode 40. In addition, the semiconductor light emitting device 120 further includes a high resistance part 45. The configuration of the first semiconductor layer 10, the light emitting layer 30, the second semiconductor layer 20, the third semiconductor layer 60, the second electrode 80, and the first electrode 40 is similar to that in the semiconductor light emitting device 110, and hence the description thereof is omitted. The pattern of the narrow wire 82a in the semiconductor light emitting device 120 is as illustrated in FIG. 4A.

The high resistance part 45 is provided between the first electrode 40 and the first semiconductor layer 10. As projected on the plane (X-Y plane) perpendicular to the stacking direction (Z-axis direction), the high resistance part 45 overlaps the narrow wire 82a.

As projected on the X-Y plane, the high resistance part 45 includes a portion 45p overlapping the narrow wire 82a. In this example, as projected on the X-Y plane, the high resistance part 45 also includes a portion 45q overlapping the pad section 81. However, as described later, the portion 45q overlapping the pad section 81 may be omitted.

The resistance of the high resistance part 45 is higher than the resistance of the first semiconductor layer 10. Alternatively, the contact resistance between the high resistance part 45 and the first semiconductor layer 10 is higher than the contact resistance between the first electrode 40 and the first semiconductor layer 10. Alternatively, the contact resistance between the high resistance part 45 and the first electrode 40 is higher than the contact resistance between the first semiconductor layer 10 and the first electrode 40.

For instance, the conductivity of the high resistance part 45 is lower than the conductivity of the first semiconductor layer 10. For instance, the electrical resistance between the first electrode 40 and the first semiconductor layer 10 in the portion where the high resistance part 45 is not provided between the first electrode 40 and the first semiconductor layer 10 is lower than the electrical resistance between the first electrode 40 and the first semiconductor layer 10 in the portion where the high resistance part 45 is provided between the first electrode 40 and the first semiconductor layer 10.

For instance, the high resistance part 45 is insulative. The high resistance part 45 can include at least one of metal oxide, metal nitride, and metal oxynitride.

For instance, in the case where the first electrode 40 is made of Ag and the first semiconductor layer 10 is made of p-type GaN, the high resistance part 45 can be made of SiO₂. Then, the contact resistance between the high resistance part 45 and the first semiconductor layer 10 is made higher than the contact resistance between the first electrode 40 and the first semiconductor layer 10.

In this example, the high resistance part 45 is embedded in the first electrode 40. However, the high resistance part 45 may be embedded in the first semiconductor layer 10.

The high resistance part 45 controls the path of current flowing from the first electrode 40 to the first semiconductor layer 10. As projected on the X-Y plane, the high resistance part 45 includes a portion overlapping the narrow wire 82a. Thus, in the portion overlapping the narrow wire 82a, the current to the light emitting layer 30 is suppressed. This suppresses light emission in this portion. Thus, light emission immediately below the light blocking narrow wire 82a is suppressed. This further increases the light emission efficiency.

FIG. 12 is a schematic sectional view illustrating another semiconductor light emitting device according to the second embodiment. FIG. 12 is a sectional view corresponding to the cross section taken along line A1-A2 of FIG. 1.

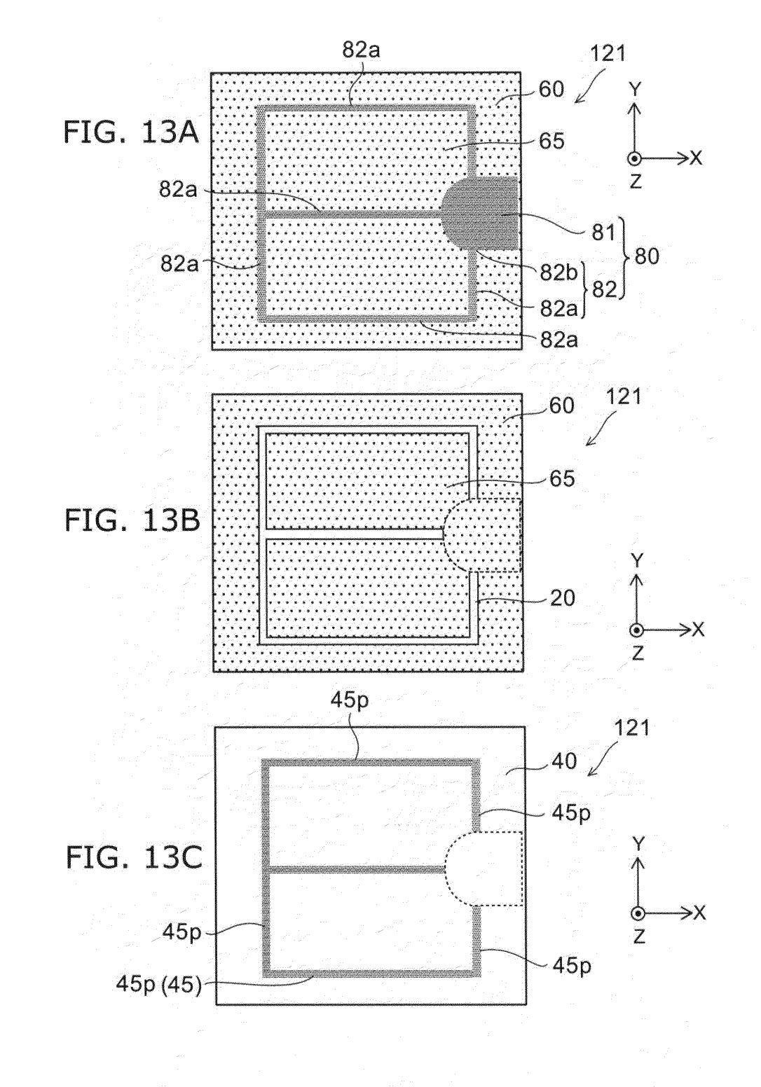

FIG. 13A to FIG. 13C are schematic plan views illustrating the another semiconductor light emitting device according to the second embodiment. FIG. 13A illustrates the planar pattern of the second electrode 80. FIG. 13B illustrates the planar pattern of the third semiconductor layer 60. FIG. 13C illustrates the planar pattern of the high resistance part 45.

As shown in FIG. 12 and FIG. 13A to FIG. 13C, the semiconductor light emitting device 121 is different from the semiconductor light emitting device 120 in the pattern of the high resistance part 45. The rest of the configuration is similar to that of the semiconductor light emitting device 120, and hence the description thereof is omitted.

In the semiconductor light emitting device 121, the portion 45q overlapping the pad section 81 is not provided. That is, as projected on the X-Y plane, the high resistance part 45 does not overlap at least part of the pad section 81. Also in this case, as projected on the X-Y plane, the high resistance part 45 includes a portion 45p overlapping the narrow wire 82a.

Immediately below the pad section 81, current injection is suppressed by the third semiconductor layer 60. Thus, immediately below the pad section 81, light emission is sufficiently suppressed without providing the high resistance part 45. Accordingly, in the high resistance part 45, the portion 45q overlapping the pad section 81 can be omitted.

In the case where the high resistance part 45 is made of e.g. SiO₂, the high resistance part 45 acts as a light absorber. Thus, by decreasing the area of the high resistance part 45, light absorption is further suppressed.

On the other hand, the narrow wire 82a is provided to spread the current in the X-Y plane. A current (e.g., electron flow) is injected from the narrow wire 82a into the semiconductor layer. The narrow wire 82a blocks (attenuates) light. Thus, it is more preferable to minimize light emission immediately below the narrow wire 82a. In the semiconductor light emitting devices 120 and 121, by providing the high resistance part 45, light emission immediately below the narrow wire 82a is suppressed. This provides higher efficiency. Furthermore, in the semiconductor light emitting device 121 in which the high resistance part 45 is shaped so as not to overlap the pad section 81, light absorption in the high resistance part 45 is suppressed. This provides higher efficiency than that of the semiconductor light emitting device 120.

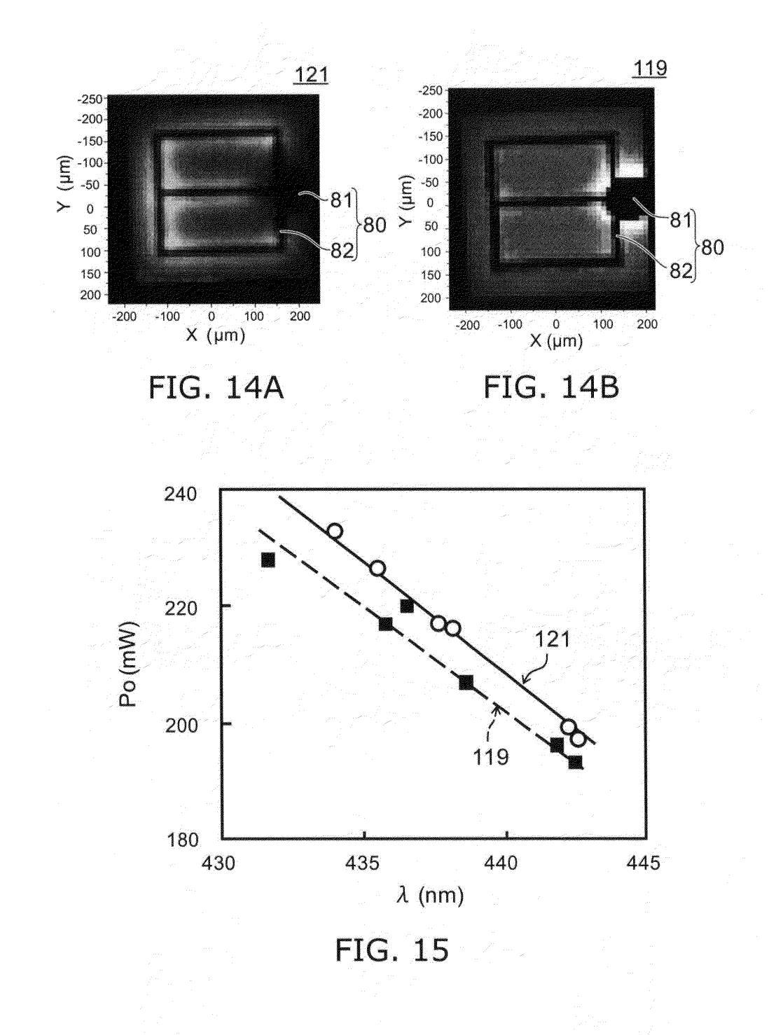

FIG. 14A and FIG. 14B are schematic plan views illustrating the characteristics of semiconductor light emitting devices.

FIG. 14A illustrates the light emission characteristics of the semiconductor light emitting device 121 according to the embodiment. FIG. 14B illustrates the characteristics of a semiconductor light emitting device 119 of a reference example. In the semiconductor light emitting device 119, the third semiconductor layer 60 is not provided. The pad section 81 and the narrow wire section 82 of the second electrode 80 are in contact with the second semiconductor layer 20. Furthermore, in the semiconductor light emitting device 119, the high resistance part 45 is not provided. In these figures, the light portion represents high brightness of light emission, and the dark portion represents low brightness of light emission.

As shown in FIG. 14B, in the semiconductor light emitting device 119 of the reference example, light emission locally occurs around the pad section 81. The brightness is low in the portion far from the pad section 81. Thus, in the semiconductor light emitting device 119, light emission is non-uniform within the surface.

As shown in FIG. 14A, in the semiconductor light emitting device 121 according to the embodiment, local light emission around the pad section 81 is suppressed. Thus, the in-plane uniformity of light emission is improved. In this example, high brightness is achieved also in the portion far from the pad section 81. This example is intended to show that local light emission around the pad section 81 can be suppressed by the third semiconductor layer 60. Thus, the brightness in the portion far from the pad section 81 is higher than the brightness around the pad section 81. However, as described later, by design change of the pattern of the narrow wire section 82, the in-plane uniformity of brightness can be further improved.

FIG. 15 is a graph illustrating the characteristics of the semiconductor light emitting device.

This figure illustrates the measurement result of optical output Po of the semiconductor light emitting device 121 and the semiconductor light emitting device 119. The horizontal axis of FIG. 15 represents wavelength λ (nm). The vertical axis of FIG. 15 represents optical output Po (milliwatt, mW).

As shown in FIG. 15, the semiconductor light emitting device 121 according to the embodiment provides higher optical output Po than the semiconductor light emitting device 119 of the reference example. For instance, the optical output Po of the semiconductor light emitting device 121 is approximately 5% higher than the optical output Po of the semiconductor light emitting device 119.

As an alternative configuration of the semiconductor light emitting device 119 (referred to as semiconductor light emitting device 119a), it is also possible to provide only the high resistance part 45 without providing the third semiconductor layer 60. This also suppresses light emission immediately below the pad section 81 and the narrow wire 82a, and increases the optical output. According to experiments by the inventor, the optical output Po of the semiconductor light emitting device 119a of this configuration is approximately 3% higher than the optical output Po of the semiconductor light emitting device 119.

In the semiconductor light emitting device 110 according to the first embodiment, the high resistance part 45 is not provided. The optical output of the semiconductor light emitting device 110 is approximately 2.5% higher than the optical output Po of the semiconductor light emitting device 119. The semiconductor light emitting device 110 is advantageous in achieving high efficiency by the simple configuration and process of leaving the third semiconductor layer 60.

According to the second embodiment, both the third semiconductor layer 60 and the high resistance part 45 are provided. Thus, very high efficiency is achieved.

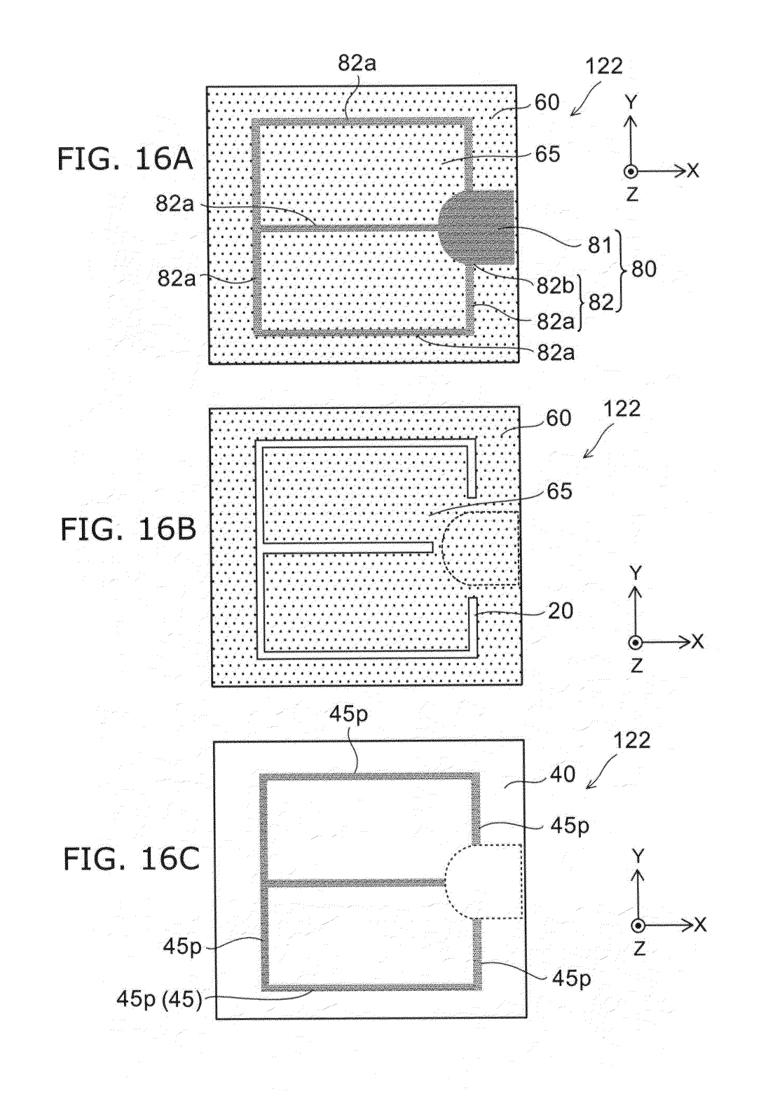

FIG. 16A to FIG. 16C are schematic plan views illustrating an alternative semiconductor light emitting device according to the second embodiment. FIG. 16A illustrates the planar pattern of the second electrode 80. FIG. 16B illustrates the planar pattern of the third semiconductor layer 60. FIG. 16C illustrates the planar pattern of the high resistance part 45.

As shown in FIG. 16A to FIG. 16C, the semiconductor light emitting device 122 is different from the semiconductor light emitting device 121 in the pattern of the second semiconductor layer 20 exposed from the third semiconductor layer 60 (i.e., the pattern of the narrow wire section 82). The rest of the configuration is similar to that of the semiconductor light emitting device 121, and hence the description thereof is omitted.

As shown in FIG. 16B, in the semiconductor light emitting device 122, the pattern of the second semiconductor layer 20 exposed from the third semiconductor layer 60 is separated from the pattern of the pad section 81. A connecting section 82b is provided between the pad section 81 and the second semiconductor layer 20 exposed from the third semiconductor layer 60.

Light emitted from one point in the light emitting layer 30 travels in the semiconductor layer while spreading. Thus, the light extraction efficiency is increased by separating the light emitting position by a certain distance from the pad section 81 blocking (attenuating) light. The distance along the X-Y plane between the pad section 81 and the end of the second semiconductor layer 20 exposed from the third semiconductor layer 60 is e.g. 1 times or more the thickness of the second semiconductor layer 20 and the third semiconductor layer 60. Here, a distance of approximately 10 times or less is preferable. For instance, the thickness of the third semiconductor layer 60 is 2 μm or more and 3 μm or less. Then, the distance along the X-Y plane between the pad section 81 and the end of the second semiconductor layer 20 exposed from the third semiconductor layer 60 is e.g. 5 μm or more and 20 μm or less.

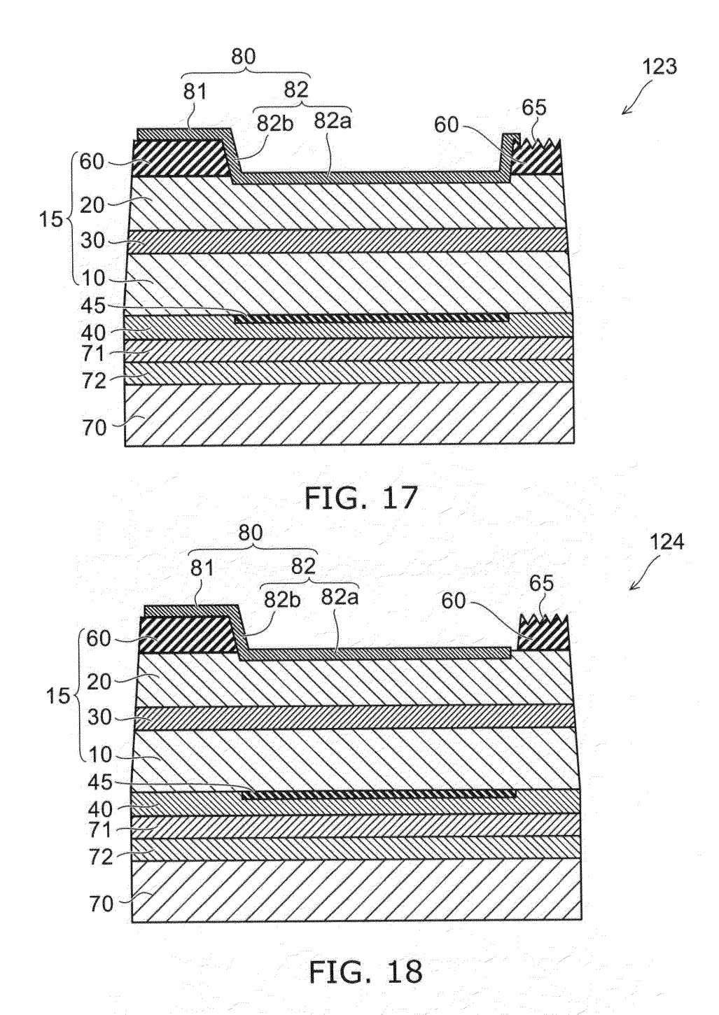

FIG. 17 to FIG. 19 are schematic sectional views illustrating other semiconductor light emitting devices according to the second embodiment. FIG. 17 to FIG. 19 are sectional views corresponding to the cross section taken along line A1-A2 of FIG. 1.

As shown in FIG. 17, in the semiconductor light emitting device 123 according to the embodiment, part of the second electrode 80 extends also on the third semiconductor layer 60. The rest is the same as the semiconductor light emitting device 121.

As shown in FIG. 18, in the semiconductor light emitting device 124 according to the embodiment, the end of the portion extending along the X-Y plane (narrow wire 82a) of the narrow wire section 82 is spaced from the third semiconductor layer 60. The rest is the same as the semiconductor light emitting device 121.

In the semiconductor light emitting device 123 or 124, for instance, the pattern shape of the second electrode 80 has a wide margin and facilitates manufacturing.

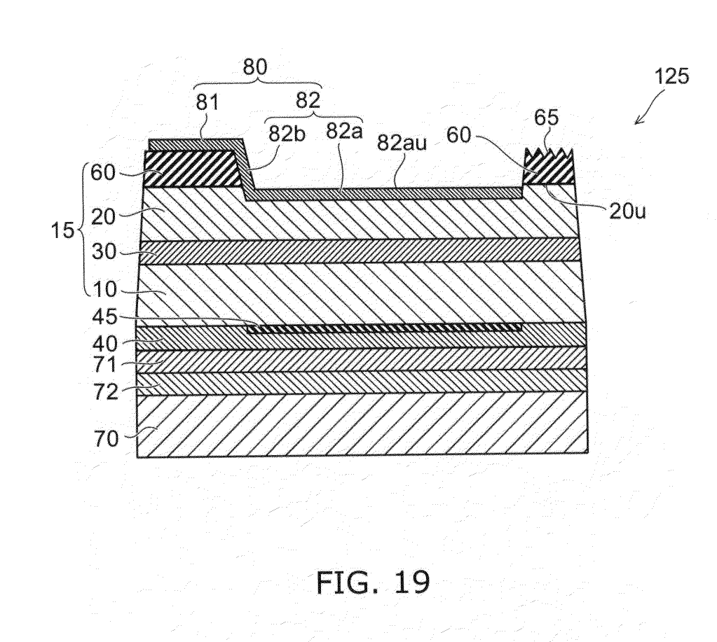

As shown in FIG. 19, in the semiconductor light emitting device 125 according to the embodiment, the upper surface 82au of the portion extending along the X-Y plane (narrow wire 82a) of the narrow wire section 82 is located below the upper surface 20u of the second semiconductor layer 20. The rest is the same as the semiconductor light emitting device 121. In the semiconductor light emitting device 125, at least one of e.g. the thickness of the second semiconductor layer 20, the depth of the trench 60t formed in the third semiconductor layer 60, and the thickness of the second electrode 80 has a wide margin and facilitates manufacturing.

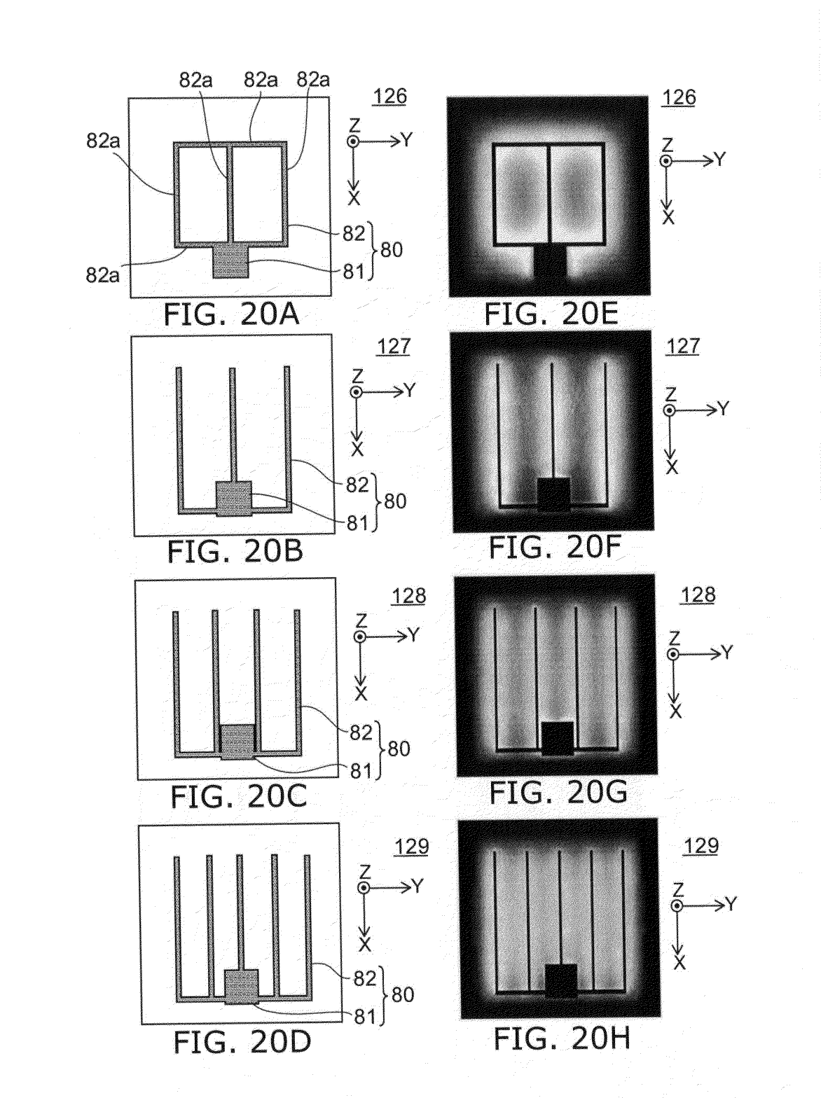

FIG. 20A to FIG. 20H are schematic plan views illustrating the configuration and characteristics of semiconductor light emitting devices according to the second embodiment.

These figures illustrate the result of simulating the light emission characteristics for different pattern shapes of the second electrode 80. FIG. 20A to FIG. 20D show the shape of the second electrode 80 in the semiconductor light emitting devices 126-129 according to the embodiment. FIG. 20E to FIG. 20H show the in-plane distribution of the brightness of light emission in the semiconductor light emitting devices 126-129, respectively. In FIG. 20E to FIG. 20H, the light portion represents high brightness, and the dark portion represents low brightness. In these examples, the configuration of the high resistance part 45 is the same as the configuration in the semiconductor light emitting device 121. That is, the high resistance part 45 is provided at the position overlapping the narrow wire 82a, and is not provided at the position overlapping the pad section 81.

As shown in FIG. 20A, in the semiconductor light emitting device 126, three narrow wires 82a extending in the X-axis direction are connected at both ends by two narrow wires 82a extending in the Y-axis direction. As shown in FIG. 20E, in the semiconductor light emitting device 126, light emission does not concentrate only on the neighborhood of the pad section 81, but also occurs around the narrow wires 82a. Thus, the light emission has high in-plane uniformity.

As shown in FIG. 20B, in the semiconductor light emitting device 127, three narrow wires 82a extending in the X-axis direction are connected at one end by one narrow wire 82a extending in the Y-axis direction. The other end of the three narrow wires 82a is left open. As shown in FIG. 20F, in the semiconductor light emitting device 127, light emission around the pad section 81 is further suppressed, and light emission along the narrow wires 82a is further promoted.

As shown in FIG. 20C, in the semiconductor light emitting device 128, four narrow wires 82a extending in the X-axis direction are connected at one end by one narrow wire 82a extending in the Y-axis direction. The other end of the four narrow wires 82a is left open. As shown in FIG. 20G, the semiconductor light emitting device 128 has higher in-plane uniformity of light emission than the semiconductor light emitting device 127.

As shown in FIG. 20D, in the semiconductor light emitting device 129, five narrow wires 82a extending in the X-axis direction are connected at one end by one narrow wire 82a extending in the Y-axis direction. The other end of the five narrow wires 82a is left open. As shown in FIG. 20H, in the semiconductor light emitting device 129, in-plane uniformity of light emission is made higher than in the semiconductor light emitting device 128.

The in-plane uniformity of light emission can be improved by narrowing the pitch of a plurality of narrow wires 82a extending in the Y-axis direction. However, with the increase of the number of narrow wires 82a, the light extraction efficiency decreases. The width of each narrow wire 82a is set so that the resistance of the narrow wire 82a is made sufficiently low.

In the semiconductor light emitting devices 127-129, the in-plane distribution of light emission is further improved. Thus, in the case where a plurality of narrow wires 82a (the portions extending along the X-Y plane) are provided, preferably, at least two of the plurality of narrow wires 82a are not connected to each other at the end on the opposite side from the pad section 81.

In the first and second embodiments, the third semiconductor layer 60 can be variously configured as follows.

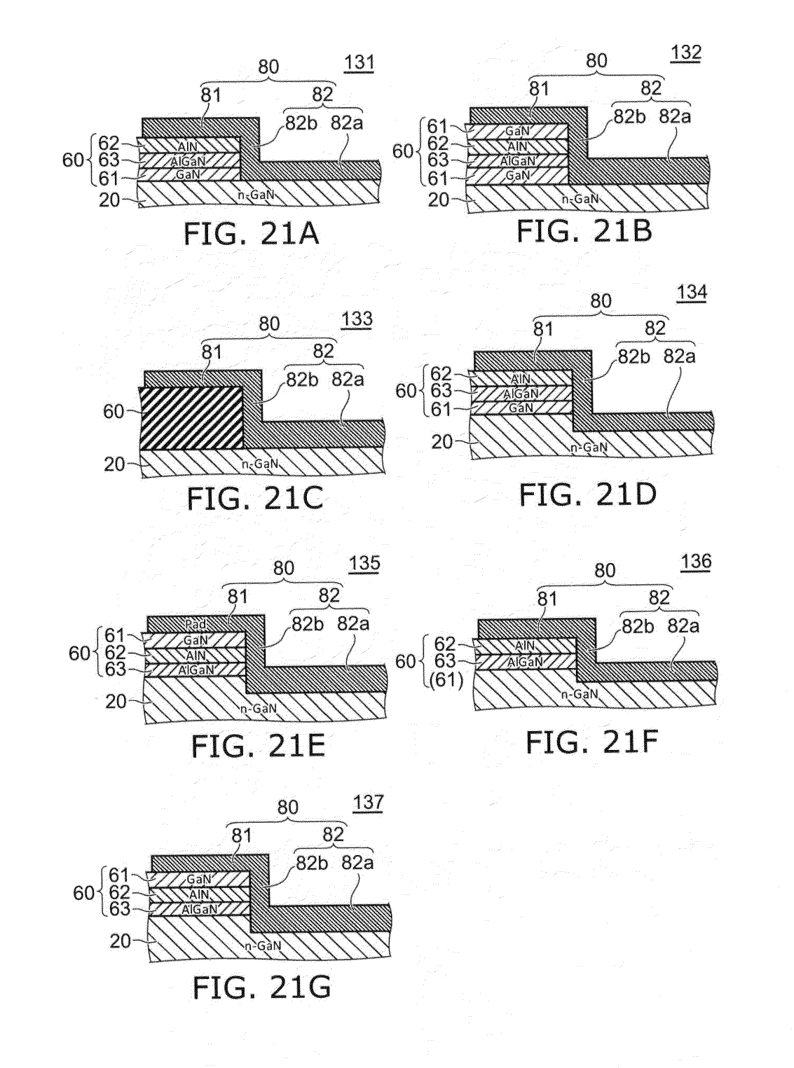

FIG. 21A to FIG. 21G are schematic sectional views illustrating semiconductor light emitting devices according to the embodiments.

These figures illustrate the configuration of the second semiconductor layer 20 and the third semiconductor layer 60 along with the second electrode 80. These figures are sectional views corresponding to part of the sectional view illustrated in FIG. 2.

As shown in FIG. 21A, in the semiconductor light emitting device 131 according to the embodiments, the third semiconductor layer 60 is provided on the second semiconductor layer 20 (e.g., n-type GaN layer). The third semiconductor layer 60 includes a first layer 61 (e.g., GaN layer), a third layer 63 (e.g., AlGaN layer) provided on the first layer 61, and a second layer 62 (e.g., AlN layer) provided on the third layer 63. The pad section 81 is in contact with the second layer 62. The narrow wire section 82a is in contact with the second semiconductor layer 20.

As shown in FIG. 21B, in the semiconductor light emitting device 132 according to the embodiments, the third semiconductor layer 60 is provided on the second semiconductor layer 20 (e.g., n-type GaN layer). The third semiconductor layer 60 includes a first layer 61 (e.g., GaN layer), a third layer 63 (e.g., AlGaN layer), and a second layer 62 (e.g., AlN layer). The third semiconductor layer 60 further includes another first layer 61 on the second layer 62. The pad section 81 is in contact with the upper first layer 61. The narrow wire section 82a is in contact with the second semiconductor layer 20.

As shown in FIG. 21C, in the semiconductor light emitting device 133 according to the embodiments, the third semiconductor layer 60 is provided on the second semiconductor layer 20 (e.g., n-type GaN layer). The third semiconductor layer 60 includes e.g. a plurality of first layers 61 and a plurality of second layers 62 stacked alternately (e.g., see FIG. 5). The third semiconductor layer 60 may further include a third layer 63 provided between the first layer 61 and the second layer 62.

As shown in FIG. 21D, in the semiconductor light emitting device 134 according to the embodiments, the thickness of a portion of the second semiconductor layer 20 (e.g., n-type GaN layer) is thicker than the thickness of the other portion. The third semiconductor layer 60 is provided on the aforementioned thick portion. The third semiconductor layer 60 includes a first layer 61 (e.g., GaN layer), a third layer 63 (e.g., AlGaN layer) provided on the first layer 61, and a second layer 62 (e.g., AlN layer) provided on the third layer 63. The pad section 81 is in contact with the second layer 62. The narrow wire section 82a is in contact with the second semiconductor layer 20.

As shown in FIG. 21E, also in the semiconductor light emitting device 135 according to the embodiments, the thickness of a portion of the second semiconductor layer 20 (e.g., n-type GaN layer) is thicker than the thickness of the other portion. The third semiconductor layer 60 is provided on the aforementioned thick portion. The third semiconductor layer 60 includes a third layer 63 (e.g., AlGaN layer), a second layer 62 (e.g., AlN layer) provided on the third layer 63, and a first layer 61 (e.g., GaN layer) provided on the second layer 62. The pad section 81 is in contact with the first layer 61. The narrow wire section 82a is in contact with the second semiconductor layer 20.

As shown in FIG. 21F, also in the semiconductor light emitting device 136 according to the embodiments, the thickness of a portion of the second semiconductor layer 20 (e.g., n-type GaN layer) is thicker than the thickness of the other portion. The third semiconductor layer 60 is provided on the aforementioned thick portion. The third semiconductor layer 60 includes a third layer 63 (e.g., AlGaN layer) and a second layer 62 (e.g., AlN layer) provided on the third layer 63. The pad section 81 is in contact with the second layer 62. The narrow wire section 82a is in contact with the second semiconductor layer 20. The configuration of the semiconductor light emitting device 136 may also be regarded as a configuration in which the third semiconductor layer 60 includes a first layer 61 (e.g., AlGaN layer) and a second layer 62 (e.g., AlN layer) provided on the first layer 61. Thus, the second layer 62 is a layer having higher Al composition ratio than the first layer 61. The first layer 61 may be made of AlGaN, and the second layer 62 may be made of AlN.

As shown in FIG. 21G, also in the semiconductor light emitting device 137 according to the embodiments, the thickness of a portion of the second semiconductor layer 20 (e.g., n-type GaN layer) is thicker than the thickness of the other portion. The third semiconductor layer 60 is provided on the aforementioned thick portion. The third semiconductor layer 60 includes a third layer 63 (e.g., AlGaN layer), a second layer 62 (e.g., AlN layer) provided on the third layer 63, and a first layer 61 (e.g., GaN layer) provided on the second layer 62. The pad section 81 is in contact with the first layer 61. The narrow wire section 82a is in contact with the second semiconductor layer 20.

In order to increase the efficiency of the light emitting device based on nitride semiconductor, it is desired to suppress current concentration on the neighborhood of the pad section of the n-side electrode. By suppressing current concentration, uniform light emission distribution is obtained within the surface, and the light emission efficiency is increased. As a method for suppressing current concentration to improve the light emission efficiency, it may be considered to provide an insulating layer between the second semiconductor layer 20 and the pad section 81 of the n-side electrode. However, use of such an insulating layer decreases the reliability due to large difference in thermal conductivity, or due to low adhesiveness between the insulating layer and the n-side electrode.

In the embodiments, the pad section 81 of the n-side electrode (second electrode 80) is formed on the third semiconductor layer 60 having low conductivity. The narrow wire section 82 is formed on the n-type second semiconductor layer 20. Thus, the in-plane light emission distribution is made uniform, and the light emission efficiency can be increased. Furthermore, the n-side electrode is formed on the third semiconductor layer 60 made of nitride semiconductor having high thermal conductivity and good adhesiveness to the electrode. This suppresses degradation due to heat generation, and suppresses peeling of the electrode. The embodiments can provide a semiconductor light emitting device having high in-plane uniformity of light emission distribution, high efficiency, and high reliability.

The embodiments can provide a semiconductor light emitting device having high efficiency.

In the specification, the “nitride semiconductor” includes semiconductors of the chemical formula BₓIn_{y}Al_{z}Ga_{1-x-y-z}N (0≦x≦1, 0≦y≦1, 0≦z≦1, x+y+z≦1) of any compositions with the composition ratios x, y, and z varied in the respective ranges. Furthermore, the “nitride semiconductor” also includes those of the above chemical formula further containing group V elements other than N (nitrogen), those further containing various elements added to control various material properties such as conductivity type, and those further containing various unintended elements.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

The embodiments of the invention have been described above with reference to examples. However, the invention is not limited to these examples. For instance, any specific configurations of various components such as the first semiconductor layer, second semiconductor layer, third semiconductor layer, light emitting layer, second electrode, first electrode, support substrate, and growth substrate included in the semiconductor light emitting device are encompassed within the scope of the invention as long as those skilled in the art can similarly practice the invention and achieve similar effects by suitably selecting such configurations from conventionally known ones.

Further, any two or more components of the specific examples may be combined within the extent of technical feasibility and are included in the scope of the invention to the extent that the purport of the invention is included.

Moreover, all display devices practicable by an appropriate design modification by one skilled in the art based on the display devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a first electrode;
a first semiconductor layer of a first conductivity type provided on the first electrode and including a nitride semiconductor;
a light emitting layer provided on the first semiconductor layer and including a nitride semiconductor;
a second semiconductor layer of a second conductivity type provided on the light emitting layer and including a nitride semiconductor;
a third semiconductor layer provided on a part of the second semiconductor layer, the third semiconductor layer including a nitride semiconductor, and having a concentration of impurity of the second conductivity type lower than a concentration of impurity of the second conductivity type in the second semiconductor layer; and
a second electrode including:
a pad section provided on the third semiconductor layer; and
a narrow wire section extending out from the pad section, the narrow wire section including an extending portion extending along a plane perpendicular to a stacking direction from the first semiconductor layer toward the second semiconductor layer, and the narrow wire section being in contact with the second semiconductor layer.

2. The device according to claim 1, further comprising:
a high resistance part provided between the first electrode and the first semiconductor layer, the high resistance part overlapping the extending portion of the narrow wire section as projected on the plane,
a resistance of the high resistance part being higher than a resistance of the first semiconductor layer.

3. The device according to claim 1, further comprising:
a high resistance part provided between the first electrode and the first semiconductor layer and overlapping the extending portion of the narrow wire section as projected on the plane,
a contact resistance between the high resistance part and the first semiconductor layer being higher than a contact resistance between the first electrode and the first semiconductor layer.

4. The device according to claim 1, further comprising:
a high resistance part provided between the first electrode and the first semiconductor layer and overlapping the extending portion of the narrow wire section as projected on the plane,
a contact resistance between the high resistance part and the first electrode being higher than a contact resistance between the first semiconductor layer and the first electrode.

5. The device according to claim 2, wherein the high resistance part does not overlap at least a part of the pad section as projected on the plane.

6. The device according to claim 1, wherein at least a part of the narrow wire section is embedded in the second semiconductor layer.

7. The device according to claim 1, wherein a material of the narrow wire section is same as a material of at least a part of the pad section.

8. The device according to claim 1, wherein an angle between the plane and a portion of a side surface of the third semiconductor layer where the second electrode is provided is 20 degrees or more and 85 degrees or less.

9. The device according to claim 8, wherein the angle between the plane and the portion of the side surface of the third semiconductor layer where the second electrode is provided is same as an angle between the plane and a side surface of the second semiconductor layer.

10. The device according to claim 1, wherein the concentration of the impurity of the second conductivity type in the third semiconductor layer is 0.5 times or less of the concentration of the impurity of the second conductivity type in the second semiconductor layer.

11. The device according to claim 1, wherein the third semiconductor layer includes a GaN layer.

12. The device according to claim 11, wherein a concentration of the impurity of the second conductivity type in the GaN layer is 1×10¹⁸/cm³ or less.

13. The device according to claim 1, wherein the third semiconductor layer includes an Alₓ₁Ga₁₋ₓ₁N layer (0<x1≦1).

14. The device according to claim 1, wherein the third semiconductor layer has an unevenness provided on at least a portion of an upper surface of the third semiconductor layer not covered with the second electrode.

15. The device according to claim 1, wherein the portion extending along the plane is provided in a plurality, and at least two of the portions are not connected to each other at an end on an opposite side from the pad section.

16. The device according to claim 1, wherein an electrical resistance of the third semiconductor layer is twice or more of an electrical resistance of the second semiconductor layer.

17. The device according to claim 1, wherein
the second electrode contains Al, and
the first electrode contains Ag.

18. The device according to claim 1, wherein the first conductivity type is p-type, and the second conductivity type is n-type.
